(19) United States
(12) Patent Application Publication
(10) Pub. No.: US 2026/0352135 A1
(43) Pub. Date: Nov. 5, 2026

(54) MOTOR DIAGNOSIS METHOD, MOTOR DIAGNPSTIC APPARATUS, MOTOR DIAGNOSTIC DEVICE, AND MOTOR DIAGNOSTIC SYSTEM

(71) Applicant: Zhongshan Broad-Ocean Motor Co., Ltd., Zhongshan (CN)

(72) Inventors: Yuhang WANG, Zhongshan (CN); Fei YANG, Zhongshan (CN); Chao YANG, Zhongshan (CN); Zhejiang LIU, Zhongshan (CN)

(21) Appl. No.: 19/707,351

(22) Filed: Jun. 14, 2026

Related U.S. Application Data
(63) Continuation-in-part of application No. PCT/CN2025/096833, filed on May 23, 2025.

(30) Foreign Application Priority Data
Jul. 31, 2024 (CN) 202411043995.X

(51) Int. Cl. H02P 29/024; G01R 31/34

(52) U.S. Cl. CPC H02P 29/024; G01R 31/343

(57) ABSTRACT

The disclosure relates to the technical field of motor diagnostics, and more particularly to a motor diagnostic method, a motor diagnostic apparatus, a motor diagnostic device, and a motor diagnostic system. The motor diagnostic system includes a motor device, a motor diagnostic device, and an electronic device. The motor device is communicatively connected to the motor diagnostic device, and the motor diagnostic device is communicatively connected to the electronic device. The motor diagnostic device is configured to receive operating data of the motor device and an initial fault identifier transmitted by the motor device; analyze the initial fault identifier to determine target fault description information corresponding to the motor device; and transmit the target fault description information and the operating data to the electronic device for display. The disclosure reduces return-to-factory maintenance costs, improves maintenance efficiency, and enables post-sale diagnostic capability for the motor device.

### CROSS-REFERENCE TO RELATED APPLICATIONS

This application is a continuation-in-part of International Patent Application No. PCT/CN2025/096833 with an international filing date of May 23, 2025, designating the United States, now pending, further claims foreign priority benefits to Chinese Patent Application No. 202411043995.X filed Jul. 31, 2024. The contents of all of the aforementioned applications, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, MA 02142.

### BACKGROUND

The disclosure relates to the field of motor diagnostics, and more particularly, to a motor diagnosis method, a motor diagnosis apparatus, a motor diagnosis device, and a motor diagnosis system.

Electric motors are widely used as driving components in air-conditioning and ventilation systems and are commonly installed together with the overall equipment in locations that are difficult to access for maintenance, such as rooftops or within walls. For thermal management purposes, motor manufacturers typically encapsulate a motor controller using a potting material and fixedly integrate the controller with a motor housing. In such configurations, only communication lines are exposed from the motor controller, and the communication lines are routed together with power and control wire harnesses through reserved structural openings, so as to transmit motor operating information to an air-conditioning main control board or another control unit.

When an abnormal condition occurs in the air-conditioning and ventilation system, isolating and determining whether the motor itself is faulty generally requires maintenance personnel to perform on-site inspection using specialized tools. As a result, fault localization is time-consuming and technically challenging.

Accordingly, there exists a need for an effective solution for diagnosing motor faults.

### SUMMARY

To solve the aforesaid problems, it is a first objective of the disclosure to provide a motor diagnosis method.

The motor diagnosis method is applied to a motor diagnostic system. The motor diagnostic system comprises a motor device, a motor diagnostic device, and an electronic device. The motor device is communicatively connected to the motor diagnostic device, and the motor diagnostic device is communicatively connected to the electronic device. The motor diagnosis method comprises:
receiving, by the motor diagnostic device, operating data and an initial fault identifier transmitted from the motor device;
analyzing, by the motor diagnostic device, the initial fault identifier to determine target fault description information indicative of an operating condition of the motor device; and
transmitting, by the motor diagnostic device, the target fault description information and the operating data to the electronic device for display.

The motor diagnostic device receives operating data corresponding to the motor device and the initial fault identifier transmitted by the motor device. The motor diagnostic device analyzes the initial fault identifier to determine target fault description information corresponding to the motor device, and then transmits the target fault description information and the operating data to the electronic device, such that the electronic device displays the target fault description information and the operating data. As a result, maintenance personnel are enabled to locate a fault position of the motor device based on the displayed target fault description information and the operating data, thereby improving the efficiency of motor diagnosis. In addition, the motor diagnosis method reduces return-to-factory maintenance costs, improves maintenance efficiency, and enables post-sale diagnostic capability for the motor device.

In one embodiment of the disclosure, analyzing the initial fault identifier to determine the target fault description information comprises:
identifying the operating data to determine a candidate fault identifier indicative of an operating condition of the motor device;
comparing the initial fault identifier with the candidate fault identifier; and
determining the target fault description information based on a result of the comparing.

The motor diagnosis method identifies the operating data so as to determine candidate fault identifiers corresponding to the motor device, thereby improving the accuracy of the determined candidate fault identifiers. The initial fault identifier is compared with the candidate fault identifiers, and the target fault description information corresponding to the motor device is determined based on the result of the comparison, thereby improving the accuracy of the determined target fault description information. In the motor diagnosis method, inaccuracies arising from determining target fault description information solely based on the initial fault identifier are thereby avoided.

In one embodiment of the disclosure, determining the target fault description information based on a result of the comparing comprises:
in response to the initial fault identifier matching the candidate fault identifier, determining the target fault description information for the initial fault identifier based on a predetermined mapping between fault identifiers and fault description information.

When the initial fault identifier matches the candidate fault identifier, the target fault description information corresponding to the initial fault identifier is determined based on the predefined correspondence between fault identifiers and fault description information, thereby improving the accuracy of the determined target fault description information.

In one embodiment of the disclosure, determining the target fault description information based on a result of the comparing further comprises:
in response to the initial fault identifier not matching the candidate fault identifier, determining first fault description information corresponding to the initial fault identifier and second fault description information corresponding to the candidate fault identifier, based on the predetermined mapping between fault identifiers and fault description information; and
combining the first fault description information and the second fault description information to generate the target fault description information.

When the initial fault identifier is inconsistent with the candidate fault identifier, the first fault description information corresponding to the initial fault identifier and second fault description information corresponding to the candidate fault identifier are determined based on a predefined correspondence between fault identifiers and fault description information, thereby improving the accuracy of the determined first and second fault description information. The first fault description information and the second fault description information are integrated to generate target fault description information, thereby improving the accuracy of the generated target fault description information. In the motor diagnostic method, inaccuracies resulting from determining target fault description information solely based on the initial fault identifier are thereby avoided.

In one embodiment of the disclosure, subsequent to transmitting the target fault description information and the operating data to the electronic device, the motor diagnostic method further comprises:
in response to the target fault description information indicating that a program of the motor device has not been updated, receiving, by the motor diagnostic device, a program update file transmitted by the electronic device, the program update file being configured to update a current program of the motor device;
verifying the program update file;
upon successful verification of the program update file, transmitting, by the motor diagnostic device, the program update file to the motor device via a communication connection established between the motor diagnostic device and the motor device; and
upon unsuccessful verification of the program update file, receiving, by the motor diagnostic device, the program update file retransmitted by the electronic device.

When the target fault description information indicates that the program of the motor device has not been updated, the program update file transmitted from the electronic device is received and verified, thereby ensuring the correctness of the program update file. Upon successful verification of the program update file, the program update file is transmitted to the motor device via the communication connection established between the motor diagnostic device and the motor device, thereby ensuring the correctness of the program update file delivered to the motor device. The motor device updates a current program based on the program update file, thereby eliminating the fault condition of the motor device and ensuring normal operation of the electronic device. The motor diagnostic method overcomes the problem in the prior art in which program optimization or upgrade for new or existing motors is difficult due to encapsulation material covering a chip-integrated programming port. When the verification of the program update file is unsuccessful, the program update file retransmitted by the electronic device is received, thereby preventing an inaccurate program update file from being delivered to the motor device and adversely affecting normal operation thereof.

In one embodiment of the disclosure, verifying the program update file comprises:
verifying the program update file based on a preset verification method to generate a target verification value;
transmitting the target verification value to the electronic device, such that the electronic device compares the target verification value with an initial verification value corresponding to the program update file to generate verification result information;
receiving the verification result information transmitted by the electronic device; and
determining whether the verification of the program update file has been completed successfully based on the verification result information.

The program update file is verified based on the predefined verification method to generate the target verification value, thereby improving the accuracy of the generated target verification value. The target verification value is transmitted to the electronic device, such that the electronic device compares the target verification value with the initial verification value corresponding to the program update file to generate verification result information. The verification result information is received from the electronic device, and whether the verification of the program update file has been completed successfully is determined based on the verification result information, thereby improving the accuracy of the determination result regarding the successful verification of the program update file.

In one embodiment of the disclosure, the motor diagnostic method further comprises:
receiving, by the motor diagnostic device, a user instruction from the electronic device;
reading, based on the user instruction, a target program file stored in a storage device operatively associated with the motor diagnostic device; and
transmitting, by the motor diagnostic device, the target program file to the motor device.

The user instruction is received, and the target program file stored in the storage device operatively associated with the motor diagnosis device is read in response to the user instruction, thereby ensuring the accuracy of the target program file. The target program file is then transmitted to the motor device, thereby ensuring that the motor device successfully receives the target program file. The motor diagnostic method addresses problems in the prior art in which data upload and download via a cloud server suffer from low success rates due to weak 4G/5G signal coverage or severe electromagnetic interference at industrial sites, resulting in unstable wireless signal transmission.

It is a second object of the disclosure to provide a motor diagnostic apparatus. The motor diagnostic apparatus is applied to the motor diagnostic device operating in the motor diagnostic system. The motor diagnostic apparatus comprises:
a receiving module configured to receive operating data corresponding to the motor device and an initial fault identifier transmitted by the motor device;
a determining module configured to analyze the initial fault identifier to determine target fault description information corresponding to the operating condition of the motor device; and
a transmitting module configured to transmit the target fault description information and the operating data to the electronic device, such that the electronic device displays the target fault description information and the operating data.

The motor diagnostic apparatus receives the operating data and the initial fault identifier transmitted from the motor device, analyzes the initial fault identifier, and determines the target fault description information corresponding to the motor device, thereby improving the accuracy of the determined target fault description information and enabling motor diagnosis. The target fault description information and the operating data are then transmitted to the electronic device for display, such that maintenance personnel are enabled to locate a fault position of the motor device based on the target fault description information and the operating data, thereby improving the efficiency of motor diagnosis. In addition, the motor diagnostic apparatus addresses problems in the prior art involving excessive cost and diminished efficiency associated with returning motor devices to a factory for maintenance, as well as the inability to provide effective after-sales diagnostic support.

In one embodiment of the disclosure, subsequent to transmitting the target fault description information and the operating data to the electronic device,
the receiving module is further configured to, in response to the target fault description information indicating that the program of the motor device has not been updated, receive the program update file transmitted by the electronic device, the program update file being configured to update the current program of the motor device;
the determining module is further configured to verify the program update file;
the transmitting module is further configured to, in response to the successful verification of the program update file, transmit the program update file to the motor device via the communication connection established between the motor diagnostic device and the motor device; and
the receiving module is further configured to, in response to the unsuccessful verification of the program update file, receive the program update file retransmitted by the electronic device.

In one embodiment of the disclosure, the receiving module is further configured to receive the user instruction;
the determining module is further configured to read, based on the user instruction, the target program file stored in the storage device operatively associated with the motor diagnostic device; and
the transmitting module is further configured to transmit the target program file to the motor device.

It is a third objective of the disclosure to provide a motor diagnostic device. The motor diagnostic device comprises a memory and at least one processor communicatively coupled to the memory. The memory is configured to store computer-executable instructions that, when executed by the at least one processor, cause the at least one processor to perform the motor diagnosis method.

It is a fourth objective of the disclosure to provide a motor diagnostic system. The motor diagnostic system comprises the motor device, the motor diagnostic device, and the electronic device. The motor device is communicatively connected to the motor diagnostic device, and the motor diagnostic device is configured to perform the motor diagnosis method described hereinabove.

It is a fifth objective of the disclosure to provide a non-transitory computer-readable storage medium configured to store the computer-executable instructions that, when executed by a computer, cause the computer to perform the motor diagnosis method described hereinabove.

It is a sixth objective of the disclosure to provide a computer program product comprising the computer-executable instructions that, when executed by the computer, cause the computer to perform the motor diagnosis method.

### BRIEF DESCRIPTION OF THE DRAWINGS

FIG. 1 is a schematic diagram of a motor diagnosis system according to an embodiment of the disclosure;

FIG. 2 is a schematic diagram of a motor diagnosis system according to another embodiment of the disclosure;

FIG. 3 is a flowchart of a motor diagnosis method according to an embodiment of the disclosure;

FIG. 4 is a flowchart of a motor diagnosis method according to another embodiment of the disclosure;

FIG. 5 is a flowchart of a motor diagnosis method according to a further embodiment of the disclosure;

FIG. 6 is a block diagram illustrating data transmission of a motor diagnosis device according to an embodiment of the disclosure;

FIG. 7 is a schematic diagram illustrating offline program upgrading of a motor device according to an embodiment of the disclosure;

FIG. 8 is a schematic diagram of a motor diagnosis apparatus according to an embodiment of the disclosure; and

FIG. 9 is a schematic diagram illustrating a hardware structure of a motor diagnosis device according to an embodiment of the disclosure.

### DETAILED DESCRIPTION

To further illustrate the disclosure, embodiments detailing the motor diagnosis method, the motor diagnosis apparatus, the motor diagnosis device, and the motor diagnosis system are described below. It should be noted that the following embodiments are intended to describe and not to limit the disclosure.

Electric motors are widely used as driving components in air-conditioning and ventilation systems and are commonly installed together with the overall equipment in locations that are difficult to access for maintenance, such as rooftops or within walls. For thermal management purposes, motor manufacturers typically encapsulate a motor controller using a potting material and fixedly integrate the motor controller with a motor housing. In such configurations, only communication lines are exposed from the motor controller, and the communication lines are routed together with power and control wire harnesses through reserved structural openings, so as to transmit motor operating information to an air-conditioning main control board or another control unit.

When an abnormal condition occurs in the air-conditioning and ventilation system, isolating and determining whether the motor itself is faulty generally requires maintenance personnel to perform on-site inspection using specialized tools. As a result, fault localization is time-consuming and technically challenging.

Accordingly, there exists a need for an effective solution for diagnosing motor faults.

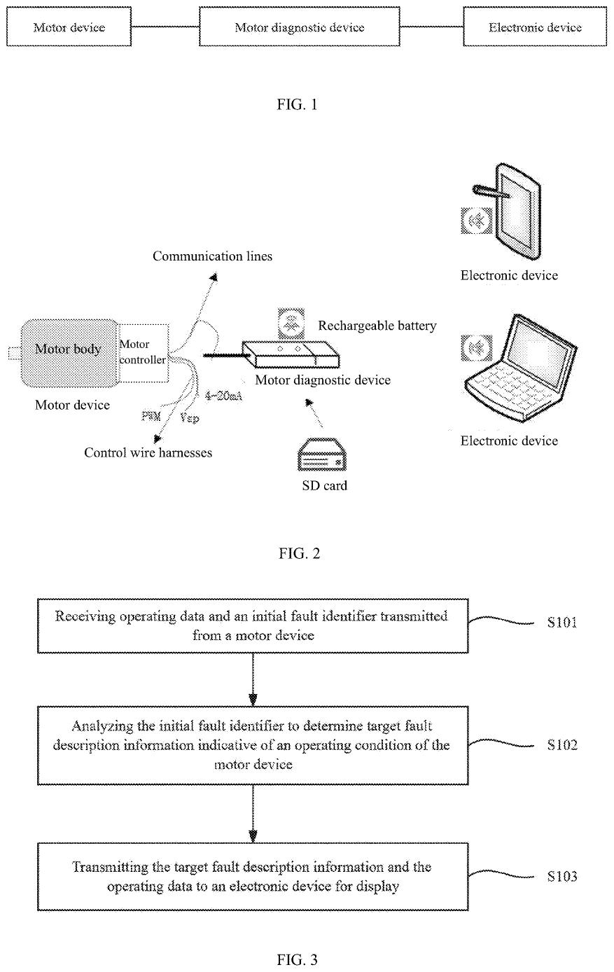

The disclosure provides a motor diagnosis method implemented by a motor diagnostic device operating in a motor diagnostic system. As shown in FIG. 1, the motor diagnostic system comprises a motor device, a motor diagnostic device, and an electronic device. The motor device is communicatively connected to the motor diagnostic device, and the motor diagnostic device is communicatively connected to the electronic device.

As shown in FIG. 2, the motor device comprises a motor controller. The electronic device may be a terminal device, such as a mobile phone, a computer, or a tablet computer. The disclosure does not impose limitations on the specific type or form factor of the electronic device.

In certain embodiments, the motor controller is provided with control wire harnesses and a communication line. The motor diagnostic device may be connected to the motor controller via the communication line, and the electronic device is wirelessly connected to the motor diagnostic device, for example, via Bluetooth or Wi-Fi. The motor diagnostic device further comprise a rechargeable battery configured to supply electrical power thereto.

The communication line may employ a communication protocol exhibiting enhanced anti-interference capability, such as RS-485, RS-422, or controller area network (CAN) communication.

RS-485, referring to Recommended Standard 485, is a serial communication standard employing differential signal transmission. RS-485 provides substantial resistance and supports long-distance and multi-node communication. RS-422, referring to Recommended Standard 422, is also a serial communication interface standard utilizing differential signal transmission. Unlike RS-485, RS-422 supports full-duplex communication, whereas RS-485 supports half-duplex communication. CAN, referring to Controller Area Network, is a serial communication network capable of effectively supporting distributed control or real-time control. CAN is characterized by high performance and high reliability and is widely applied in automotive electronics and industrial automation.

The communication connection between the motor diagnostic device and the electronic device may be implemented using any suitable wireless communication method, such as near-field communication (NFC), LoRa communication, or infrared communication, or using a wired communication method, such as a Universal Serial Bus (USB) connection. NFC is a short-range, high-frequency wireless communication technology that enables contactless point-to-point data exchange between electronic devices over a short distance. LoRa is a low-power wide-area communication technology characterized by long transmission distance and low power consumption, and is suitable for application scenarios with high requirements on communication range and power efficiency.

Specifically, the motor diagnostic device receives operating data corresponding to a motor device and an initial fault identifier transmitted by the motor device. The motor diagnostic device analyzes the initial fault identifier so as to determine target fault description information corresponding to the motor device, and then transmits the target fault description information and the operating data to an electronic device, such that the electronic device displays the target fault description information and the operating data. As a result, maintenance personnel are enabled to locate a fault position of the motor device based on the displayed target fault description information and operating data, thereby improving the efficiency of motor diagnosis. In addition, the motor diagnosis method reduces return-to-factory maintenance costs, improves maintenance efficiency, and enables post-sale diagnostic capability for the motor device.

In accordance with embodiments of the present disclosure, a motor diagnosis method is provided. It should be noted that the steps depicted in the flowcharts of the accompanying drawings are executed in a computer system. Although a logical order is illustrated in the flowcharts, in certain implementations the illustrated or described steps may be performed in an order different from that depicted herein.

In one embodiment of the present disclosure, a motor diagnosis method is provided. The motor diagnosis method is applicable to the motor diagnostic device operating in the motor diagnostic system. The motor diagnostic system comprises a motor device, a motor diagnostic device, and an electronic device. The motor device is in communication with the motor diagnostic device. FIG. 3 illustrates a flowchart of a motor diagnosis method according to an embodiment of the disclosure. As shown in FIG. 3, the method comprises the following steps.

At step S101: the motor diagnostic device receives operating data of the motor device and an initial fault identifier transmitted from the motor device.

Specifically, the motor diagnostic device periodically transmits request information to the motor controller so as to read the operating data and the initial fault identifier.

Upon receiving the request information from the motor diagnostic device, the motor controller transmits the operating data of the motor device and the initial fault identifier to the motor diagnostic device.

It should be noted that the initial fault identifier may be generated by the motor controller upon performing fault diagnosis based on the operating data of the motor device.

The operating data may include, but is not limited to, a direct-current (DC) bus voltage, an actual rotational speed, and other operating parameters associated with operation of the motor device.

By way of example and not limitation, Table 1 illustrates communication data exchanged between the motor diagnostic device and the motor device.

TABLE 1
Communication Data Exchanged Between the Motor
Diagnostic Device and the Motor Device

| | | | Message Sent from | |
|---|---|---|---|---|
| | | | Motor Diagnostic | Message Returned from |
| | | | Device to Motor | Motor Controller to Motor |
| | Functional | Command | Controller (Input | Diagnostic Device (Output |
| No. | Description | Code | Frame) | Frame) |
| 1 | Reading DC bus | 0x01 | 81 + 06 + 01 + 00 + | 18 + 06 + 01 + |
| | voltage | | 00 + checksum | DATA + checksum |
| 2 | Reading actual | 0x02 | 81 + 06 + 02 + 00 + | 18 + 06 + 02 + |
| | rotational speed | | 00 + checksum | DATA + checksum |
| 3 | Reading motor | 0x03 | 81 + 06 + 03 + 00 + | 18 + 06 + 03 + |
| | fault code | | 00 + checksum | DATA + checksum |

In some embodiments, DATA represents the initial fault identifier, and the DATA comprises two bytes.

At step S102, the motor diagnostic device analyzes the initial fault identifier so as to determine target fault description information of the motor device.

Specifically, upon receiving the initial fault identifier, the motor diagnostic device analyzes the initial fault identifier based on a predefined correspondence relationship between fault identifiers and fault description information, thereby determining target fault description information corresponding to the motor device.

By way of example and not limitation, the correspondence relationship between fault identifiers and fault description information is predefined as illustrated in Table 2 below.

TABLE 2
Exemplary Correspondence Between Fault Identifiers
and Fault Description Information

| No. | Fault Identifier | Fault Description Information |
|---|---|---|
| 1 | 0x0000 | Normal operation |
| 2 | 0x0001 | Overtemperature protection |
| 3 | 0x0002 | Three-phase power phase loss |
| 4 | 0x0003 | Overcurrent protection |
| 5 | 0x0004 | Rotor stall protection during motor startup |
| 6 | 0x0005 | Output phase loss fault |
| 7 | 0x0006 | Undervoltage fault |
| 8 | 0x0007 | Overvoltage fault |

In an optional embodiment, the target fault description information supports fault superposition. In such embodiments, when a plurality of faults occur simultaneously, the motor controller generates a composite initial fault identifier by combining fault identifiers corresponding to the respective fault condition. For example, where a first fault condition comprising an overtemperature protection fault corresponds to a first initial fault identifier having a value of 0x0001, and a second fault condition comprising an overcurrent protection fault corresponds to a second initial fault identifier having a value of 0x0004, the motor controller computes and transmits the composite initial fault identifier of having a value of 0x0005. The composite fault identifier represents the simultaneous occurrence of the first fault condition and the second fault condition. Specifically, upon resolution of the overcurrent protection fault, the motor controller automatically clears the first initial fault identifier and retains only the second initial fault identifier associated with the overcurrent protection fault.

At step S103, the motor diagnostic device transmits the target fault description information and the operating data to the electronic device, such that the electronic device displays the target fault description information and the operating data.

Specifically, upon determination of the target fault description information, the motor diagnostic device transmits the target fault description information and the operating data to the electronic device. In certain embodiments, the transmission is performed in accordance with a standard Modbus RTU protocol format. The electronic device is configured to display the target fault description information and the operating data.

In an optional embodiment of the present disclosure, the motor diagnostic device is further configured to store motor feedback data directly to a removable storage medium, such as a Secure Digital (SD) card, and to present the target fault description information and the operating data via a digital display module.

In another optional embodiment of the present disclosure, the motor diagnostic device is configured to store the target fault description information and the operating data in a storage space accessible to the motor diagnostic device, and to present the target fault description information and the operating data via a digital display module.

The motor diagnosis method is implemented by performing the following operations: receiving the operating data and initial fault identifier transmitted by the motor device; and analyzing the initial fault identifier so as to determine target fault description information corresponding to the motor device.

The motor diagnosis method improves the accuracy of the target fault description information and enables diagnosis of the motor device. Upon determination of the target fault description information, the target fault description information and the operating data are presented to a user, such that maintenance personnel are enabled to identify and locate a fault position within the motor device based on the target fault description information and the operating data, thereby improving the overall efficiency of motor diagnosis. Furthermore, the motor diagnosis method addresses deficiencies in the prior art, including, but not limited to, excessive return-to-factory maintenance costs, reduced maintenance efficiency, and the inability to perform post-sale diagnostics for motor devices.

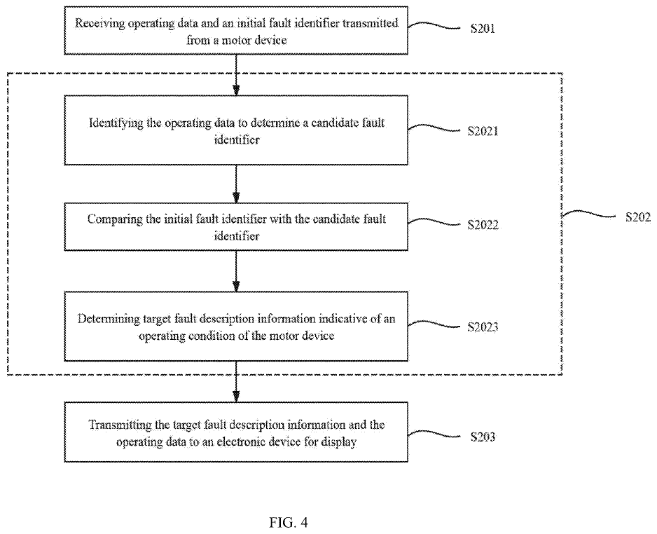

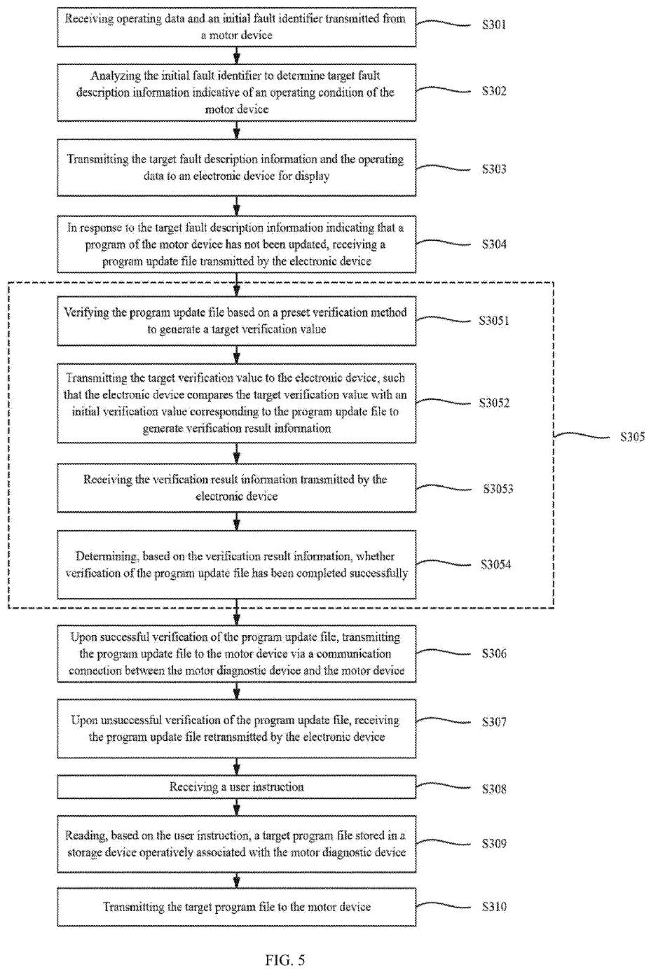

The motor diagnosis method is applicable to the motor diagnostic device operating in the motor diagnostic system. In one embodiment of the present disclosure, the motor diagnostic system comprises a motor device, a motor diagnostic device, and an electronic device. The motor device is in communication with the motor diagnostic device. FIG. 4 illustrates a flowchart of the motor diagnosis method according to an embodiment of the present disclosure. As shown in FIG. 4, the method comprises the following steps set forth below.

At step S201, the motor diagnostic device receives the operating data and initial fault identifier transmitted by the motor device.

The details of step S201 may correspond to those described hereinabove with respect to step S101, and accordingly a repeated description thereof is omitted for the sake of brevity.

At step S202: the motor diagnostic device analyzes the initial fault identifier so as to determine target fault description information corresponding to the motor device.

Specifically, step S202 comprises step S2021, in which the motor diagnostic device identifies the operating data so as to determine a candidate fault identifier corresponding to the motor device.

Specifically, the motor diagnostic device is configured to input the operating data into a preset fault identification model, and to determine the candidate fault identifier corresponding to the motor device based on an output generated by the preset fault identification model.

The preset fault identification model may include, but is not limited to, one or more of the following: a radial basis function (RBF) network, a feedforward neural network (FFNN), a convolutional neural network (CNN), a deconvolutional network (DN), a deep convolutional inverse graphics network (DCIGN), a generative adversarial network (GAN), a recurrent neural network (RNN), a long short-term memory (LSTM) network, a deep residual network (DRN), or an extreme learning machine (ELM). The present disclosure is not limited to any specific type of the preset fault identification model.

In a further embodiment of the present disclosure, the preset fault identification model is generated by a training process performed on preset training data. The preset training data comprises training operating data corresponding to one or more motor devices and training fault identifiers corresponding to the training operating data.

At step S2022, the motor diagnostic device compares the initial fault identifier with the candidate fault identifier determined in step S2021.

Specifically, the motor diagnostic device performs a comparison between the initial fault identifier received from the motor device and the candidate fault identifier generated by the preset fault identification model.

At step S2023, the motor diagnostic device determines target fault description information corresponding to the motor device based on a result of the comparison performed in step S2022.

Specifically, step S2023 comprises the following operations.

In step a1, when the initial fault identifier is consistent with the candidate fault identifier, the motor diagnostic device determines target fault description information corresponding to the initial fault identifier or the candidate fault identifier based on a predefined correspondence relationship between fault identifiers and fault description information.

In step a2: when the initial fault identifier is inconsistent with the candidate fault identifier, the motor diagnostic device determines first fault description information corresponding to the initial fault identifier and second fault description information corresponding to the candidate fault identifier based on the correspondence relationship between fault identifiers and fault description information.

In step a3: the motor diagnostic device integrates the first fault description information and the second fault description information to generate the target fault description information.

At step S203, the motor diagnostic device transmits the target fault description information and the operating data to the electronic device, such that the electronic device displays the target fault description information and the operating data.

The details of step S203 may correspond to those described hereinabove with respect to step S103, and therefore a repeated description thereof is omitted for the sake of brevity.

In another embodiment of the present disclosure, the operating data of the motor device is analyzed so as to determine a candidate fault identifier corresponding thereto, thereby improving the accuracy of the candidate fault identifier. The initial fault identifier received from the motor device is compared with the candidate fault identifier. When the initial fault identifier is consistent with the candidate fault identifier, the target fault description information corresponding to the initial fault identifier is determined based on a predefined correspondence relationship between fault identifiers and correspondence fault description information, thereby ensuring accuracy of the target fault description information. When the initial fault identifier is inconsistent with the candidate fault identifier, the first fault description information corresponding to the initial fault identifier and the second fault description information corresponding to the candidate fault identifier are determined, thereby improving the accuracy of the first fault description information and the second fault description information. The first fault description information and the second fault description information are then integrated so as to generate the target fault description information, thereby improving the accuracy of the generated target fault description information and avoiding inaccuracies that may otherwise result from determining target fault description information solely based on the initial fault identifier.

In the present embodiment, a motor diagnostic method is provided, which is applicable to the motor diagnostic device operating in the motor diagnostic system described hereinabove. The motor diagnostic system comprises a motor device, a motor diagnostic device, and an electronic device. The motor device is in communication with the motor diagnostic device.

FIG. 5 illustrates a flowchart of a motor diagnostic method according to an embodiment of the present disclosure. As shown in FIG. 5, the method comprises the following steps.

At step S301, the motor diagnostic device receives operating data corresponding to the motor device and an initial fault identifier transmitted by the motor device.

The details of step S301 may correspond to those described hereinabove with respect to step S201, and therefore a repeated description thereof is omitted for the sake of brevity.

At step S302, the motor diagnostic device analyzes the initial fault identifier so as to determine target fault description information corresponding to the operating condition of the motor device.

The details of step S302 may correspond to those described hereinabove with respect to step S202, and therefore a repeated description thereof is omitted for the sake of brevity.

At step S303, the motor diagnostic device transmits the target fault description information and the operating data to the electronic device, such that the electronic device displays the target fault description information and the operating data.

The details of step S303 may correspond to those described hereinabove with respect to step S203, and therefore a repeated description thereof is omitted for the sake of brevity.

Step S304: when the target fault description information indicates that a program of the motor device has not been updated, the motor diagnostic device receives a program update file transmitted by the electronic device.

The program update file is configured to update a current program stored in the motor device.

Specifically, when the target fault description information indicates that the program of the motor device has not been updated, the electronic device receives a program update file input by a user or receive a program update file transmitted by another device. Upon receipt of the program update file, and upon a further determination that the target fault description information indicates that the program of the motor device has not been updated, the electronic device transmits the program update file to the motor diagnostic device via a communication connection therebetween in accordance with a Ymodem protocol, such that the motor diagnostic device receives the program update file transmitted by the electronic device.

Alternatively, after receiving a user input instruction for transmitting the program update file, the electronic device transmits the program update file to the motor diagnostic device via the communication connection therebetween in accordance with the Ymodem protocol.

The program update file is not limited to a binary (.bin) file, and further comprise a hexadecimal (.hex) file, a Motorola S-record (.mot) file, or other file formats, depending on a program type supported by the motor controller.

At step S305, the motor diagnostic device verifies the program update file.

Specifically, step S305 comprises step S3051.

At step S3051, the motor diagnostic device verifies the program update file based on a preset verification method so as to generate a target verification value.

Specifically, the motor diagnostic device verifies the program update file based on the preset verification method to generate the target verification value. The preset verification method may include, but is not limited to, one or more of the following: a parity check, a cyclic redundancy check (CRC), a hash verification, or other suitable verification method. The present disclosure does not impose limitations on the specific type of present verification method employed.

Specifically, Step S305 comprises step S3052.

At Step S3052, the motor diagnostic device transmits the target verification value to the electronic device, such that the electronic device compares the target verification value with an initial verification value corresponding to the program update file so as to generate verification result information.

Specifically, the motor diagnostic device transmits the target verification value to the electronic device. The electronic device compares the target verification value with the initial verification value corresponding to the program update file to generate the verification result information. When the target verification value matches the initial verification value, the verification result information indicates that the verification of the program update file is successful. When the target verification value is inconsistent with the initial verification value, the verification result information indicates that the verification of the program update file is unsuccessful.

At step S3053: the motor diagnostic device receives the verification result information transmitted by the electronic device.

At step S3054, the motor diagnostic device determines, based on the verification result information, whether the verification of the program update file has been completed successfully.

Specifically, the motor diagnostic device evaluates the verification result information received from the electronic device. When the verification result information indicates that the target verification value is consistent with the initial verification value, the motor diagnostic device determines that the verification of the program update file has been completed successfully. When the verification result information indicates that the target verification value is inconsistent with the initial verification value, the motor diagnostic device determines that the verification of the program update file has been completed unsuccessfully.

Step S306: when the verification of the program update file has been completed successfully, the motor diagnostic device transmits the program update file to the motor device via a communication connection established with the motor device.

Specifically, upon successful verification of the program update file, the motor diagnostic device transmits the program update file to a Flash memory space of the motor controller via a wired communication interface.

At step S307: when the verification of the program update file has been completed unsuccessfully, the motor diagnostic device receives the program update file retransmitted by the electronic device.

Specifically, upon an unsuccessful verification of the program update file, the motor diagnostic device receives the program update file again from the electronic device.

In another optional embodiment of the disclosure, when the target fault description information indicates that the program in the motor device has not been updated, the motor diagnostic device receives the program update file transmitted by the electronic device and transparently transmits the received program update file to the motor device. After receiving the program update file, the motor device verifies the program update file based on a preset verification method to generate a target verification value. The motor device then transmits the target verification value to the electronic device via the motor diagnostic device, such that the electronic device compares the target verification value with the initial verification value corresponding to the program update file to generate verification result information. Based on the verification result information, it is determined whether the verification of the program update file is successful. When verification is unsuccessful, the motor diagnostic device receives the program update file retransmitted by the electronic device.

At step S308, the motor diagnostic device receives a user instruction.

At step S309, the motor diagnostic device reads, based on the user instruction, a target program file stored in a storage device operatively associated with the motor diagnostic device.

In an optional embodiment of the disclosure, upon receipt of the user instruction, the motor diagnostic device reads the target program file stored in the storage device operatively associated with the motor diagnostic device. The storage device is removably connected to the motor diagnostic device without turning off the motor diagnostic device.

By way of example and not limitation, upon receipt of the user instruction, the motor diagnostic device reads the target program file stored in a Secure Digital (SD) card associated with the motor diagnostic device via an SD card reading function.

At step S310, the motor diagnostic device transmits the target program file to the motor device.

By way of example and limitation, in an industrial environment with severe electromagnetic interference and diminished wireless signal transmission quality, the motor diagnostic device may be provided with an SD card reading function. An SD card storing the target program file is inserted into a card slot of the motor diagnostic device, and a program update button of the motor diagnostic device is actuated, such that the target program file is transmitted to the motor controller via a wired transmission link with improved shielding performance. The motor device verifies the target program file, and upon successful verification thereof, an indicator is activated to indicate completion of a program upgrade operation.

In accordance with the motor diagnostic method provided by the embodiments of the disclosure, when the target fault description information indicates that the program of the motor device has not been updated, the program update file transmitted by the electronic device is received and verified using the preset verification method so as to generate the target verification value, thereby improving accuracy of the generated target verification value. The target verification value is transmitted to the electronic device for comparison with the initial verification value corresponding to the program update file to generate verification result information, and the verification result information transmitted by the electronic device is received. Whether the verification of the program update file has been completed successfully is determined based on the verification result information, thereby ensuring the accuracy of the verification result.

When the verification of the program update file has been completed successfully, the program update file is transmitted to the motor device via the communication connection established therebetween, thereby improving accuracy of the program update file transmitted to the motor device. The motor device updates the current program based on the program update file, thereby resolving a fault of the motor device and enabling normal operation of the electronic device. This configuration addresses the problem present in the prior art, including difficulties in performing program upgrade operations in instances where built-in programming ports of new or existing motor devices are encapsulated with adhesive compound.

When the verification of the program update file has not been completed unsuccessfully, the program update file retransmitted by the electronic device is received, thereby preventing an inaccurate program update file from being transmitted to the motor device and adversely affecting normal operation thereof.

Furthermore, the motor diagnostic device may receive a user instruction and read, based on the user instruction, a target program file stored in a storage device associated with the motor diagnostic device, thereby improving the accuracy of the read target program file, and transmit the target program file to the motor device. Accordingly, the motor device is ensured to receive the target program file. This configuration addresses the problem in the prior art that, in industrial environments with insufficient 4G/5G signal coverage or severe electromagnetic interference, wireless transmission is unstable and success rates of uploading and downloading data via cloud servers are reduced.

In an optional embodiment of the disclosure, a specific implementation is described in detail below to further illustrate the principles of the motor diagnostic method provided herein,

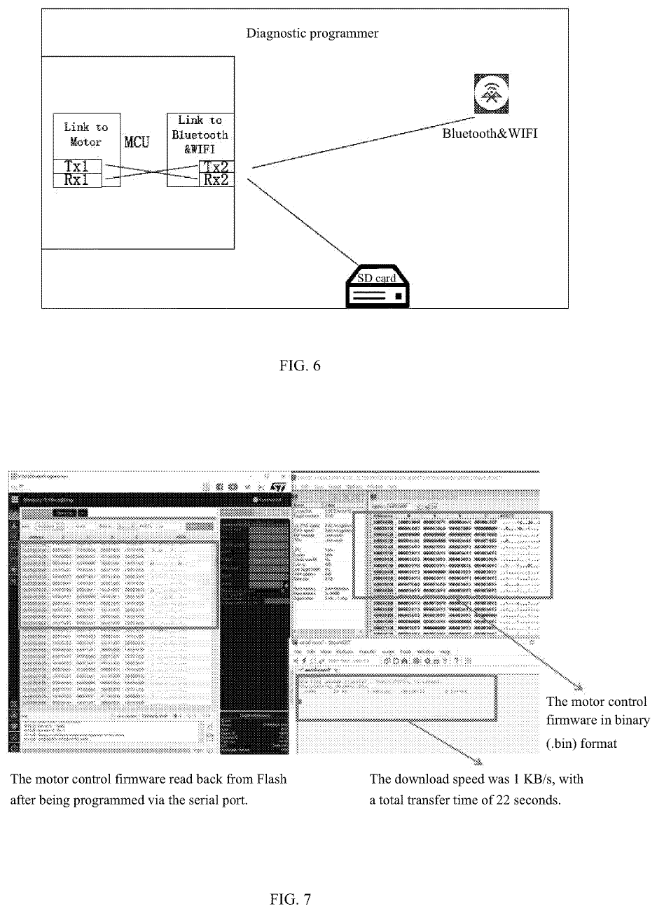

By way of example and not limitation, a DM series motor is used as an illustrative example. The communication lines comprise RT communication lines operating in a simplex mode. The motor diagnostic device comprises the motor controller configured to employ a serial-port idle interrupt mechanism and a dual-serial-port transparent transmission scheme. As shown in FIG. 6, an electronic device is configured to divide the program update file into a plurality of data streams, each having a size of 128 bytes, in accordance with a Ymodem protocol. Alternatively, the motor controller is configured to divide the target program file stored in the SD card into a plurality of data streams, each having a size of 128 bytes, in accordance with the Ymodem protocol.

The motor diagnostic device receives the data streams transmitted by the electronic device via a wireless communication interface, such as Bluetooth and/or WiFi, or reads the data streams from the SD card. The motor diagnostic device then transmits the data streams to a second data receiving port (Rx2) of the motor diagnostic device. Upon receipt of the data streams, the motor controller forwards the data streams via a first data transmission port (Tx1) to a predetermined Flash memory address of the motor controller, where Tx represents a data transmission port.

Upon completion of writing of the data streams, the motor controller transmits a response character to the motor diagnostic device via a first data receiving port (Rx1). The motor controller then forwards the response character to the electronic device via a second data transmission port (Tx2). Upon receipt of the response character, the electronic device transmits a subsequent program data stream. The foregoing operations are repeated sequentially until transmission of the target program file is completed, where Rx represents a data receiving port.

A program binary file to be updated may be read using a programming tool, such as J-Flash, as shown in the upper right portion of FIG. 7, and stored in a mobile device application of the electronic device or in the SD card. Upon completion of the program upgrade, Flash data at a predetermined memory address is read using a programming verification tool, such as STM32 CubeProgrammer. When the two sets of data are consistent, the program update is determined to have been completed successfully. As shown in FIG. 6, the electronic device may display a program file size of 29 KB, a download rate of 1 KB/sec, and a total duration of 22 seconds to complete the program upgrade of the motor controller.

By way of example and not limitation, the motor controller may read the program binary file to be updated using J-Flash and store the program binary file in the electronic device or the SD card. After completion of the program upgrade, the motor controller reads Flash data at the predetermined address using STM32 CubeProgrammer. If the two sets of data are consistent, the program update is successful. By way of example, the electronic device may display a 29 KB program update file, a download rate of 1 KB/sec, and a total duration of 22 seconds for completing the program upgrade of the motor controller.

In another embodiment of the disclosure, a motor diagnostic apparatus is further provided for implementing the foregoing embodiments of the disclosure. Details that have been described hereinabove are not repeated herein. As used herein, the term “module” refers to a software module, a hardware module, or a combination of software and hardware configured to perform a predetermined function. Although the motor diagnostic apparatus described in the following embodiments is preferably implemented in software, implementation in hardware, or in a combination of software and hardware, is also contemplated and within the scope of the disclosure.

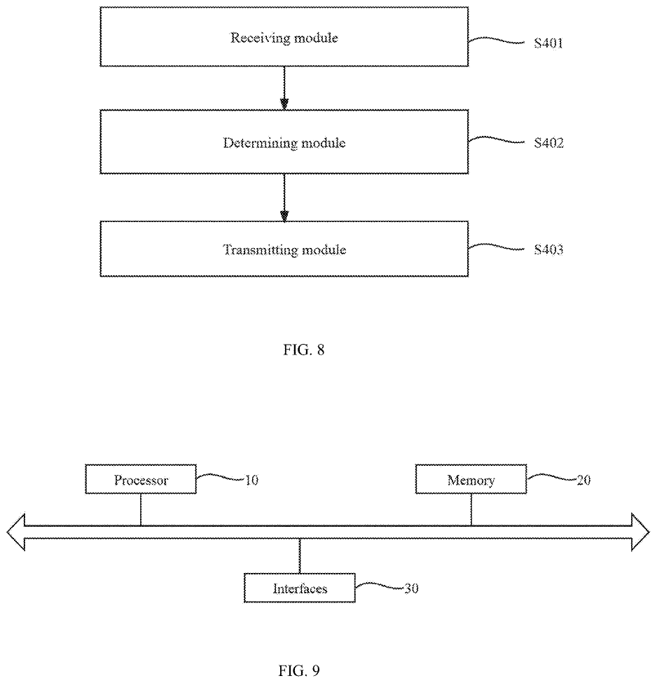

As shown in FIG. 8, the motor diagnostic apparatus is provided and applied to the motor diagnostic device operating in the motor diagnostic system. The motor diagnostic system comprises the motor device, the motor diagnostic device, and the electronic device. The motor device is in communicative communication with the motor diagnostic device, and the motor diagnostic device is in communicative communication with the electronic device. The motor diagnostic apparatus comprises:
a receiving module 401, configured to receive operating data of the motor device and an initial fault identifier transmitted by the motor device;
a determining module 402, configured to analyze the initial fault identifier so as to determine target fault description information corresponding to the motor device; and
a transmitting module 403, configured to transmit the target fault description information and the operating data to the electronic device, such that the electronic device displays the target fault description information and the operating data.

In an optional embodiment of the disclosure, subsequent to transmitting the target fault description information and the operating data to the electronic device, the receiving module 401 is further configured to, in response to the target fault description information indicating that the program of the motor device has not been updated, receive the program update file transmitted by the electronic device. The program update file is configured to update the current program of the motor device. Correspondingly, the determining module 402 is further configured to verify the program update file, and the transmitting module 403 is further configured to, in response to the successful verification of the program update file, transmit the program update file to the motor device via a communication connection established therebetween. Furthermore, the receiving module 401 is further configured to, in response to the unsuccessful verification of the program update file, receive the program update file retransmitted by the electronic device.

In another optional embodiment of the disclosure, the receiving module 401 is further configured to receive a user instruction. Correspondingly, the determining module 402 is further configured to read, based on the user instruction, a target program file stored in a storage device operatively associated with the motor diagnostic device, and the transmitting module 403 is further configured to transmit the target program file to the motor device.

Further functional descriptions of the modules and units described hereinabove are the same as those set forth in the corresponding embodiments and are not repeated herein for the sake of brevity.

The motor diagnostic apparatus of the present embodiment is described in terms of functional units. The functional units may be implemented using application-specific integrated circuit (ASIC) circuits, processors and memories executing one or more software programs or firmware programs, and/or other components capable of performing the functions described herein.

The embodiments of the present disclosure further provide a motor diagnostic device comprising the motor diagnostic apparatus shown in FIG. 8.

FIG. 9 is a schematic diagram illustrating a hardware structure of the motor diagnostic device according to an optional embodiment of the disclosure. As shown in FIG. 9, the motor diagnostic device comprises at least one processor 10, a memory 20, and a plurality of interfaces configured to connect various components thereof, including high-speed interfaces and low-speed interfaces. The components are interconnected by one or more buses and may be mounted on a common motherboard or arranged in other suitable configurations as required. The at least one processor 10 is configured to execute instructions for displaying graphical information of a graphical user interface on an external input/output device, such as a display device coupled thereto via one of the interfaces. In optional embodiments, a plurality of processors and/or a plurality of buses are used in combination with a plurality of memories. In addition, a plurality of motor diagnostic devices are interconnected, with each motor diagnostic device performing a portion of the required operations, such as in a server array, a blade server group, or a multi-processor system. FIG. 9 illustrates one processor 10 by way of example and not limitation.

The at least one processor 10 comprises a central processing unit, a network processor, or a combination thereof. The at least one processor 10 further comprises one or more hardware chips, such as application-specific integrated circuits, programmable logic devices, or a combination thereof. The programmable logic devices comprise complex programmable logic devices, field-programmable gate arrays, generic array logic, or a combination thereof.

The memory 20 is configured to store instructions that, when executable by the at least one processor 10, cause the at least one processor 10 to perform the motor diagnostic methods described in the foregoing embodiments of the disclosure.

The memory 20 comprises a program storage area and a data storage area. The program storage area is configured to store an operating system and application programs required for performing at least one function, and the data storage area is configured to store data generated based on usage of the motor diagnostic device. The memory 20 further comprises high-speed random access memory and non-transitory memory, such as magnetic disk storage devices, flash memory devices, or other non-transitory solid-state storage devices. In optional embodiments, the memory 20 comprises remotely located memory communicatively connected to the motor diagnostic device via a network. Such networks include, but are not limited to, the Internet, intranets, local area networks, mobile communication networks, or a combination thereof.

The memory 20 further comprises volatile memory, such as random access memory, and non-volatile memory, such as flash memory, hard disk drives, or solid-state drives, or a combination thereof.

The motor diagnostic device further comprises a communication interface 30 configured to enable communicative connection with other devices or communication networks.

The embodiments of the present disclosure further provide a motor diagnostic system comprising the motor device, the motor diagnostic device, and the electronic device. The motor device is in communication with the motor diagnostic device, and the motor diagnostic device is configured to execute the motor diagnostic method according to any of the foregoing embodiments of the disclosure.

The embodiments of the present disclosure further provide a computer-readable storage medium. The motor diagnostic method in accordance with the embodiments of the present disclosure may be implemented in hardware or firmware, or implemented as computer code recorded on a storage medium, or implemented as original computer code downloaded via a network and stored in a remote storage medium or a non-transitory machine-readable medium and then stored in a local storage medium. The storage medium comprises a magnetic disk, optical disc, read-only memory, random access memory, flash memory, hard disk drive, solid-state drive, or a combination thereof. It should be understood that a computer, processor, microprocessor controller, or programmable hardware device comprises storage components capable of storing or receiving software or computer program code. When the software or computer program code is accessed and executed by the computer, processor, or programmable hardware device, the methods described in the foregoing embodiments of the disclosure are implemented.

In certain embodiments of the disclosure, the motor diagnostic method is implemented as a computer program product comprising computer program instructions. When executed by a computer, the computer program instructions cause the computer to perform operations for implementing the method of the present disclosure. Computer program instructions exist in a computer-readable medium in various forms, including, but not limited to, source files, executable files, and installation package files. Execution of the computer program instructions by the computer includes, but is not limited to, direct execution of the instructions, execution of a compiled program generated from the instructions, or execution of an installed program generated after installation of the instructions. The computer-readable medium may be any available computer-readable storage medium or communication medium accessible by a computer.

It will be obvious to those skilled in the art that changes and modifications may be made, and therefore, the aim in the appended claims is to cover all such changes and modifications.

What is claimed is:

1. A motor diagnosis method, applied to a motor diagnostic system, wherein the motor diagnostic system comprises a motor device, a motor diagnostic device, and an electronic device, the motor device being communicatively connected to the motor diagnostic device, and the motor diagnostic device being communicatively connected to the electronic device, the method comprising:
receiving, by the motor diagnostic device, operating data and an initial fault identifier transmitted from the motor device;
analyzing, by the motor diagnostic device, the initial fault identifier to determine target fault description information indicative of an operating condition of the motor device; and
transmitting, by the motor diagnostic device, the target fault description information and the operating data to the electronic device for display.

2. The method of claim 1, wherein analyzing the initial fault identifier to determine the target fault description information comprises:
identifying the operating data to determine a candidate fault identifier indicative of an operating condition of the motor device;
comparing the initial fault identifier with the candidate fault identifier; and
determining the target fault description information based on a result of the comparing.

3. The method of claim 2, wherein determining the target fault description information based on a result of the comparing comprises:
in response to the initial fault identifier matching the candidate fault identifier, determining the target fault description information corresponding to the initial fault identifier based on a predetermined mapping between fault identifiers and fault description information.

4. The method of claim 2, wherein determining the target fault description information based on a result of the comparing further comprises:
in response to the initial fault identifier not matching the candidate fault identifier, determining first fault description information corresponding to the initial fault identifier and second fault description information corresponding to the candidate fault identifier, based on a predetermined mapping between fault identifiers and fault description information; and
combining the first fault description information and the second fault description information to generate the target fault description information.

5. The method of claim 1, further comprising, subsequent to transmitting the target fault description information and the operating data to the electronic device:
in response to the target fault description information indicating that a program of the motor device has not been updated, receiving, by the motor diagnostic device, a program update file transmitted by the electronic device, the program update file being configured to update a current program of the motor device;
verifying the program update file;
upon successful verification of the program update file, transmitting, by the motor diagnostic device, the program update file to the motor device via a communication connection established between the motor diagnostic device and the motor device; and
upon unsuccessful verification of the program update file, receiving, by the motor diagnostic device, the program update file retransmitted by the electronic device.

6. The method of claim 5, wherein verifying the program update file comprises:
verifying the program update file based on a preset verification method to generate a target verification value;
transmitting the target verification value to the electronic device, such that the electronic device compares the target verification value with an initial verification value corresponding to the program update file to generate verification result information;
receiving the verification result information transmitted by the electronic device; and
determining whether the verification of the program update file has been completed successfully based on the verification result information.

7. The method of claim 1, further comprising:
receiving, by the motor diagnostic device, a user instruction from the electronic device;
reading, based on the user instruction, a target program file stored in a storage device operatively associated with the motor diagnostic device; and
transmitting, by the motor diagnostic device, the target program file to the motor device.

8. A motor diagnostic apparatus for implementing the motor diagnostic method of claim 1, applied to the motor diagnostic device in the motor diagnostic system, wherein the motor diagnostic system comprises the motor device, the motor diagnostic device, and the electronic device, the motor device being communicatively connected to the motor diagnostic device, and the motor diagnostic device being communicatively connected to the electronic device, the apparatus comprising:
a receiving module configured to receive operating data corresponding to the motor device and an initial fault identifier transmitted by the motor device;
a determining module configured to analyze the initial fault identifier to determine target fault description information corresponding to the operating condition of the motor device; and
a transmitting module configured to transmit the target fault description information and the operating data to the electronic device, such that the electronic device displays the target fault description information and the operating data.

9. The apparatus of claim 8, wherein, subsequent to transmitting the target fault description information and the operating data to the electronic device,
the receiving module is further configured to, in response to the target fault description information indicating that the program of the motor device has not been updated, receive a program update file transmitted by the electronic device, the program update file being configured to update the current program of the motor device;
the determining module is further configured to verify the program update file;
the transmitting module is further configured to, in response to the successful verification of the program update file, transmit the program update file to the motor device via the communication connection between the motor diagnostic device and the motor device; and
the receiving module is further configured to, in response to the unsuccessful verification of the program update file, receive the program update file retransmitted by the electronic device.

10. The apparatus of claim 8, wherein:
the receiving module is further configured to receive a user instruction;
the determining module is further configured to read, based on the user instruction, the target program file stored in the storage device operatively associated with the motor diagnostic device; and
the transmitting module is further configured to transmit the target program file to the motor device.

11. A motor diagnostic device, comprising:
a memory; and
at least one processor communicatively coupled to the memory,
wherein the memory is configured to store computer-executable instructions that, when executed by the at least one processor, cause the at least one processor to perform the motor diagnosis method of claim 1.

12. A motor diagnostic system, comprising:
a motor device;
a motor diagnostic device; and
an electronic device,
wherein the motor device is communicatively connected to the motor diagnostic device, and the motor diagnostic device is configured to perform the motor diagnosis method of claim 1.

13. A non-transitory computer-readable storage medium, storing computer-executable instructions that, when executed by a computer, cause the computer to perform the motor diagnosis method of claim 1.

14. A computer program product comprising computer-executable instructions that, when executed by a computer, cause the computer to perform the motor diagnosis method of claim 1.
